(19) United States
(12) Patent Application Publication
(10) Pub. No.: US 2023/0420350 A1
(43) Pub. Date: Dec. 28, 2023

(54) HYPER DENSITY PACKAGE SUBSTRATE AND MEMORY COUPLED TO A MODIFIED SEMI-ADDITIVE PROCESS BOARD

(71) Applicant: Intel Corporation, Santa Clara, CA (US)

(72) Inventors: Kavitha NAGARAJAN, Bangalore (IN); Eng Huat GOH, Ayer Itam (MY); Min Suet LIM, Gelugor (MY); Telesphor KAMGAING, Chandler, AZ (US); Chee Kheong YOON, Bayan Lepas (MY); Jooi Wah WONG, Bukit Mertajam (MY); Chu Aun LIM, Hillsboro, OR (US)

(21) Appl. No.: 17/848,630

(22) Filed: Jun. 24, 2022

(51) Int. Cl. H01L 23/498; H01L 25/065; H01L 21/48

(52) U.S. Cl. CPC H01L 23/49833; H01L 25/0652; H01L 23/49816; H01L 24/16; H01L 23/49838; H01L 21/4853; H01L 23/49822

(57) ABSTRACT

Embodiments herein relate to systems, apparatuses, techniques or processes for packages that include a die complex with a base die that is coupled with a HDP substrate that in turn is coupled with an mSAP board. The HDP substrate may have a small trace width and trace spacing, for example three μm or less, that enable the HDP substrate to be used as a pitch translator between the base die and the mSAP board, for example between a 110 μm pitch and a 210 μm pitch. One or more DRAM modules may be coupled with the mSAP board. The configuration has a reduced overall package height. Other embodiments may be described and/or claimed.

### FIELD

Embodiments of the present disclosure generally relate to the field of package assemblies, and in particular package assemblies that include dynamic random-access memory (DRAM) on a substrate.

### BACKGROUND

Continued reduction in end product size of mobile electronic devices such as smart phones, tablets and ultrabooks is a driving force for the development of reduced size system in package components. In particular, this includes reducing the height of packages that include DRAM memory modules.

### BRIEF DESCRIPTION OF THE DRAWINGS

FIG. 1 illustrates a cross section side view and a perspective view of a legacy package that includes a DRAM and a die complex that is coupled with a package substrate, which in turn is coupled with a printed circuit board (PCB).

FIGS. 2A-2B illustrate a top-down view, a cross section side view, and a perspective view of a hyper density package (HDP) substrate and DRAM that are coupled with a modified semi-additive process (mSAP) board, in accordance with various embodiments.

FIG. 3 illustrates a detailed cross section side view and a top-down view of an HDP substrate as a pitch translator between a die complex base die and an mSAP board, in accordance with various embodiments.

FIG. 4 is a diagram of a cross section side view of mSAP board layers with example thicknesses, in accordance with various embodiments.

FIG. 5 is a diagram that shows differences of heights between various components of a legacy package and various components of a package that includes an HDP substrate and DRAM coupled to an mSAP board, in accordance with various embodiments.

FIGS. 6A-6E illustrate stages in a manufacturing process for coupling an HDP substrate and one or more DRAM with an mSAP board, where a die complex is coupled with the HDP, in accordance with various embodiments.

FIG. 7 illustrates an example process for coupling one or more DRAM and one or more HDP substrate with an mSAP board, in accordance with various embodiments.

FIG. 8 schematically illustrates a computing device, in accordance with various embodiments.

### DETAILED DESCRIPTION

Embodiments of the present disclosure may generally relate to systems, apparatus, techniques, and/or processes directed to packages that include one or more die complexes that is coupled with an HDP substrate. The HDP substrate and one or more DRAM modules are coupled with an mSAP board. In embodiments, the HDP substrate may have a small trace width and trace spacing, for example 3 μm or less, that enable the HDP substrate to be used as a pitch translator between a base die of the one or more die complexes and the mSAP board. In one embodiment, the HDP substrate may be used to translate a 110 μm pitch of a stacked die to a 210 μm pitch of an mSAP board.

Embodiments of these configurations may use the mSAP board as a PCB for thin and light compute systems. As a result, these embodiments may achieve a reduced overall Z-height for the package as compared to legacy implementations, by removing a need for an additional substrate within the package for pitch translation. Because the Z-height of these packages is typically dominated by the height of the DRAM, eliminating a substrate and/or reducing a substrate thickness, may result in a package with reduced height. In embodiments, the mSAP board may be produced that has fewer layers than legacy substrates, for example an mSAP board with seven layers. This reduction in Z-height may be particularly significant for small form factor devices that go into the 8-11 inch segment for example but not limited to detachable devices, dual displays, and/or tablets.

Increasing customer expectations for performance improvements that result in a better overall user experience may be met by increased memory speeds within devices. These increased memory speeds may not be supported by memory modules, such as DRAM, that are electrically coupled through a traditional PCB with die complexes and other components. As a result, memory modules have been increasingly moved into a package, in which DRAM are integrated onto the package substrate. However, this approach results in an overall increase in the package Z-height dominated by the Z-height of the DRAM, and also in an increase in the overall system Z-height.

Legacy implementations, as referred to above, may include placing DRAM memory directly on a package substrate, where the package substrate may be an ultra-thin core (UTC) package with 10 layers. These legacy implementations may also use direct chip attach (DCA) techniques that are silicon-based. Although DCA and/or DCA modules, where die and memory modules are integrated, eliminate package substrates and may reduce overall Z-height, they are implemented as a silicon-based pitch translator that adds cost compared to other embodiments described herein that use HDP techniques as a translator that are substrate-based.

In embodiments described herein, an HDP substrate may directly couple a base die of a die complex, for example two-tier die stack, to an mSAP board, with one or more DRAM memory also placed on the mSAP board. As a result of this configuration, the Z-height of the package will be reduced as compared to legacy implementations in which DRAM memory is assembled onto a legacy package substrate prior to assembly onto a PCB.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

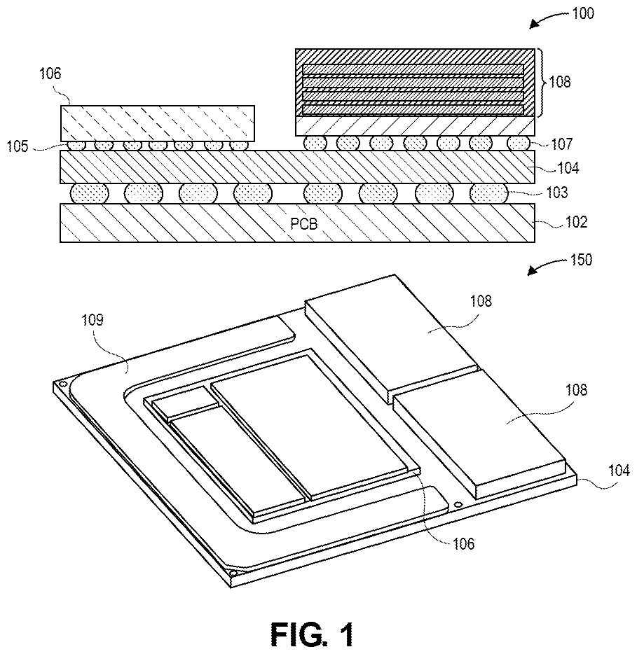

FIG. 1 illustrates a cross section side view and a perspective view of a legacy package that includes a DRAM and a die complex that is coupled with a package substrate, which in turn is coupled with a PCB. Legacy package 100 is a cross section side view of a memory package that includes a PCB 102, onto which a package substrate 104 may be attached. In embodiments, a ball grid array (BGA) 103 may be used to electrically and physically couple the package substrate 104 with the PCB 102.

In implementations, one or more die complexes 106 may be physically and electrically coupled with the package substrate 104 using a BGA 105. One or more DRAM modules 108 may be physically and electrically coupled with the package substrate 104 using BGA 107. Z-heights of a DRAM module 108 may vary, for example, a legacy 8 GB DRAM may have a Z-height of 650 μm, and a 16 GB DRAM may have a Z-height of 900 μm. In these implementations, the one or more die complexes 106 may include multiple chips, described further below, that may be used, for example, for computation or for caching as the die complexes 106 interact with the DRAM modules 108. Note that the BGAs 105, 107 may be used to provide power or signals, respectively, to the one or more die complexes 106 and DRAM modules 108.

A legacy package 150, which may be similar to package 100, shows a perspective view that includes multiple DRAM modules 108 and multiple die complexes 106 that are coupled to the substrate 104, which in turn is coupled with the PCB 102. In legacy implementations, a stiffener 109 may be placed on the package substrate 104. With respect to the Z-height of legacy packages 100, 150, this height may be determined based upon a time of the height of the DRAM module 108, the height of BGA 107, the height of package substrate 104, the height of BGA 103, and the height of PCB 102. In implementations, this overall height may range from 1.34 mm for 16 GB (2 x8 GB DRAM modules 108), up to 1.58 mm for 32 GB (2 x16 GB DRAM modules 108).

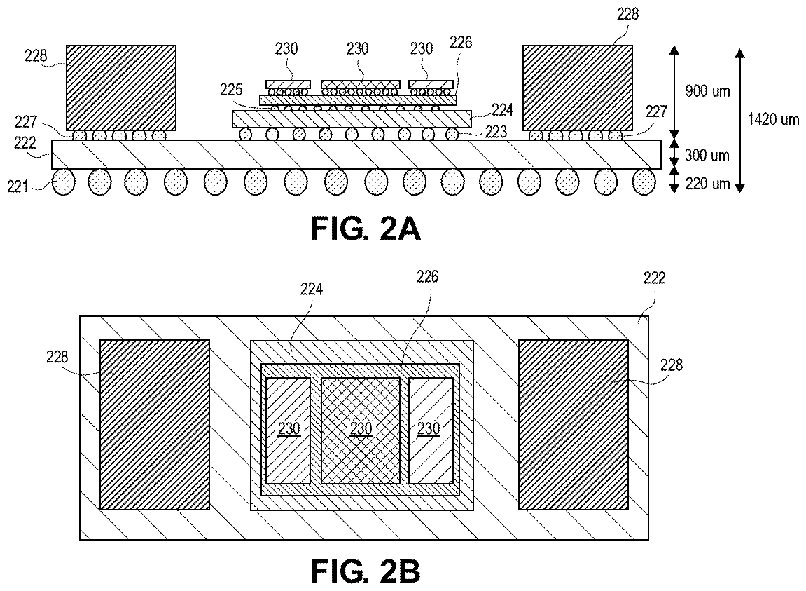

FIGS. 2A-2B illustrate a top-down view, a cross section side view, and a perspective view of a HDP substrate and DRAM that are coupled with an mSAP board, in accordance with various embodiments. FIG. 2A shows a cross section side view that includes an mSAP board 222, which may also be referred to as an mSAP PCB that has a BGA 221 on the bottom side. DRAM modules 228, which may be similar to DRAM modules 108 of FIG. 1, are electrically and physically coupled with the mSAP board 222 using BGA 227. In embodiments, the BGA 227 may deliver power and signals to the DRAM modules 228, which may be routed within layers of the mSAP board 222 that are discussed further below.

An HDP substrate 224 may be also electrically and physically coupled with the mSAP board 222 using a BGA 223. A base die 226, which may be a base die of a die complex that also includes dies 230 coupled with the base die 226, is electrically and physically coupled with the HDP substrate 224. In embodiments, the base die 226 may be part of a die stack that includes dies 230. The base die 226 may be electrically and physically coupled with the HDP substrate 224 using package side bumps (PSB) 225. In embodiments, a pitch of the PSB 225 that couples the base die 226 with the top of the HDP substrate 224 may be significantly smaller, which also may be referred to as having a tighter pitch, than a pitch of the BGA 223 that couples the mSAP board 222 with the bottom of the HDP substrate 224.

In embodiments, a trace width (TW) and a trace spacing (TS) of the HDP substrate 224 may be 3 μm or less. As a result, the HDP substrate 224 may serve as a pitch translator, translating the pitch of the PSB 225 to the pitch needed on the mSAP board 222. In embodiments, a pitch of the base die 226 may be on the order of 110 μm, where the minimum pitch needed on the mSAP board 222 may be on the order of 210 μm. As a result, the HDP substrate 224 may be used to place the die complex with base die 226 directly on the mSAP board 222.

FIG. 2B shows a top-down view of the package shown in FIG. 2A. Other embodiments may include more than two DRAM modules 228 that are electrically and physically coupled with the mSAP board 222.

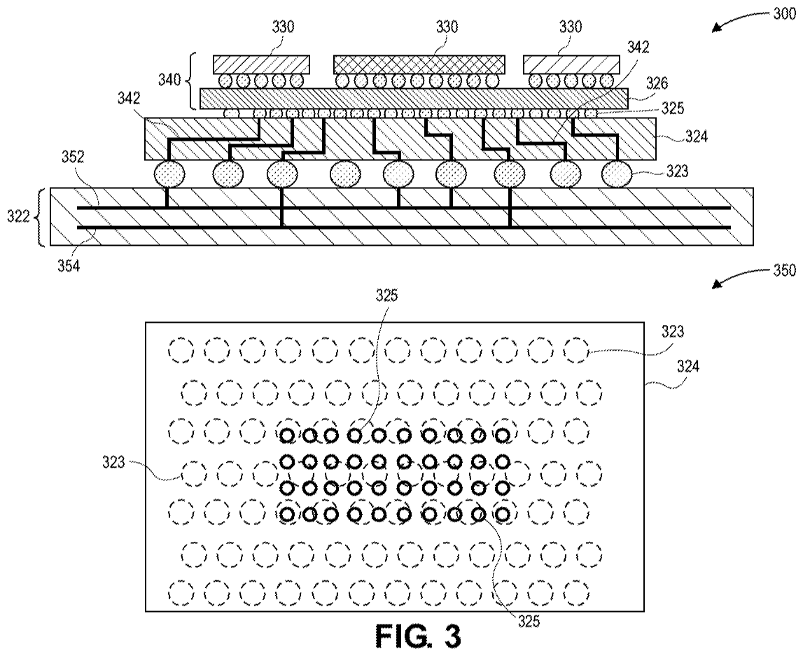

FIG. 3 illustrates a detailed cross section side view and a top-down view of an HDP substrate as a pitch translator between a die complex base die and an mSAP board, in accordance with various embodiments. Partial package 300 shows a cross section side view of a die complex 340 that includes a base die 326 and multiple dies 330 coupled with the base die 326. The base die 326 includes a PSB 325, which may be referred to as an array of interconnects that may include bumps or may be related to an array of interconnects that may include bumps that physically and electrically couples with an HDP substrate 324 at a first pitch. These may be similar to base die 226, HDP substrate 224, and PSB 225 of FIG. 2A. The HDP substrate 324 couples with an mSAP board 322 using a BGA 323, which may be referred to as an array of interconnects that may include bumps or may be related to an array of interconnects that may include bumps, that is at a second pitch, where the second pitch is greater than the first pitch.

The HDP substrate 324 may include various electrical routings 342 that electrically connect an individual PSB 325 with an individual BGA 323. Note that the routings 342 may include vertical connections that may be implemented using metal plated or metal filled vias, and horizontal connections that may be implemented using metal routings within various layers of the HDP substrate 324.

In embodiments, the HDP substrate 324 may include multiple layers (not shown), and manufactured typically using process in manufacturing package substrates.

In embodiments, the mSAP board 322, which may be similar to mSAP board 222 of FIG. 2A, may have fewer layers in comparison to legacy PCBs. As a result, the mSAP board 322 will contribute less to the overall Z-height of the package 300. In embodiments, the mSAP board 322 may include at least two mSAP layers 352, 354 which may be electrically coupled with the BGA 323. In embodiments, these mSAP layers 352, 354 may carry both signal and power, and may be electrically coupled with one or more DRAM memory modules, such as DRAM modules 228 of FIG. 2A.

In embodiments, the mSAP board 322 may have a surface layer pitch that is not lesser than 210 μm. When used in conjunction with the HDP package 324, which may have a TW of 3 μm or less and/or a TS of 3 μm or less, the HDP package 324 is able to perform pitch translation. In particular, when the base die 326 is the base die of a die stack, the HDP package 324 is able to translate from the 110 μm pitch of the die stack to the 210 μm pitch of the mSAP board 322. In embodiments, because the HDP package 324 provides such a significant pitch translation, additional substrates that may be found in legacy implementations to perform such a pitch translation are not needed.

In embodiments, the mSAP board 322 may be used as a motherboard, on thin and light compute systems, for example detachables, foldables, tables, and think and light laptops, that may comply with advanced mSAP design rules. In other embodiments, for example for systems that require 2x2+ or 3x3+PCB, the mSAP board may be used as a module that includes the HDP package 324, the die complex 340, and DRAM modules such as DRAM modules 228 of FIG. 2A.

Partial package 350, which may be similar to portions of partial package 300, shows a top-down view of an HDP package 324 that includes PSB 325, at the first pitch, and BGA 323, shown as hidden solder balls underneath the HDP package 324, at the second pitch. In embodiments, the first pitch of the PSB 325, as shown, may be significantly smaller than the second pitch of the BGA 323, wherein the various routings 342 cause the HDP package 324 to act as a pitch translator.

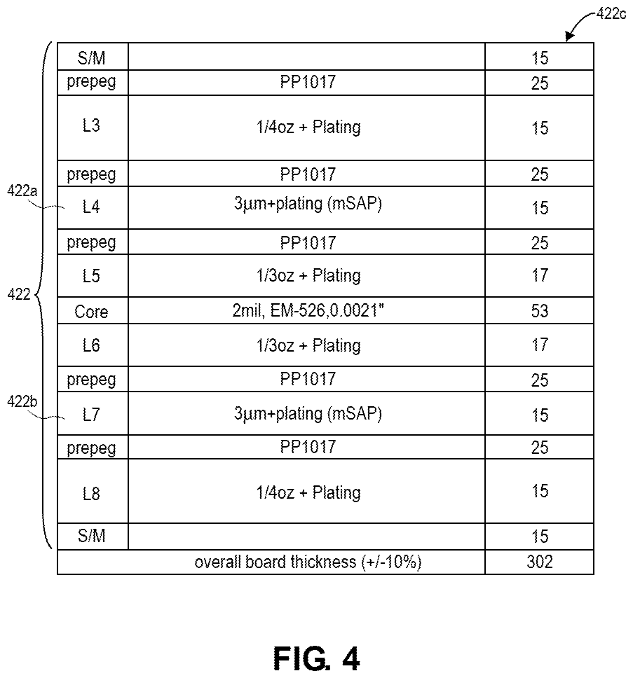

FIG. 4 is a diagram of a cross section side view of mSAP board layers with example thicknesses, in accordance with various embodiments. mSAP board 422, which may be similar to mSAP board 322 of FIG. 3 or mSAP board 222 of FIGS. 2A-2B, shows details of layers that may form a substrate stackup. mSAP board 422 may include a total of eight layers, where layer 4 422a and layer 7 422b are mSAP layers that allow signal or power routing. Limiting to these 2 layers may result in overall cost reductions. The column 422c shows example thicknesses in micrometers for each of the layers. As a result, in this embodiment, an overall thickness of the mSAP board 422 may be around 302 μm.

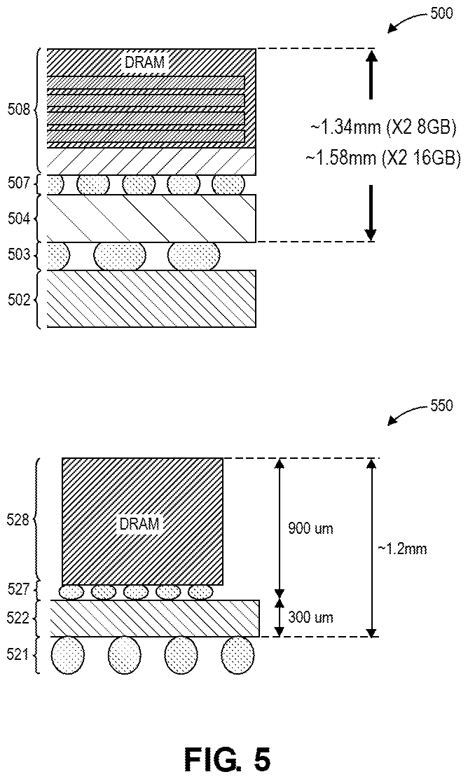

FIG. 5 is a diagram that shows differences of heights between various components of a legacy package and various components of a package that includes an HDP substrate and DRAM coupled to an mSAP board, in accordance with various embodiments. Partial legacy package 500, which may be similar to legacy package 100 of FIG. 1, shows heights of various components of the legacy package 500 that make up a total height. DRAM module 508 may be coupled with BGA 507 that is coupled with the substrate 504. These may be similar to the DRAM module 108, BGA 107, and substrate 104 of FIG. 1.

The BGA 503 may be coupled with a printed circuit board 502, which may be similar to PCB 102 of FIG. 1. In legacy implementations, the DRAM module 508 may be an 8 GB implementation (for 16 GB over memory size), which may have a height of 650 μm, or may be a 16 GB (for 32 GB over memory size) implementation which may have a height of 900 μm. As a result, the overall height of the legacy package 500 may be between 1.34 mm and 1.58 mm.

Partial package 550, which may be similar to package shown in FIG. 2A, shows an embodiment that includes a DRAM module 528 on top of the BGA 527, that in turn is coupled with an mSAP board 522 that includes BGA 521 below the mSAP board 522. These may be similar to DRAM module 228, BGA 227, mSAP board 222, and BGA 221 of FIG. 2A. With the DRAM module 528 and a 16 GB module with a height of 900 μm, the overall Z-height of the package 550 is 1.2 mm, which is substantially less than the 1.34 to 1.58 mm of legacy package 500.

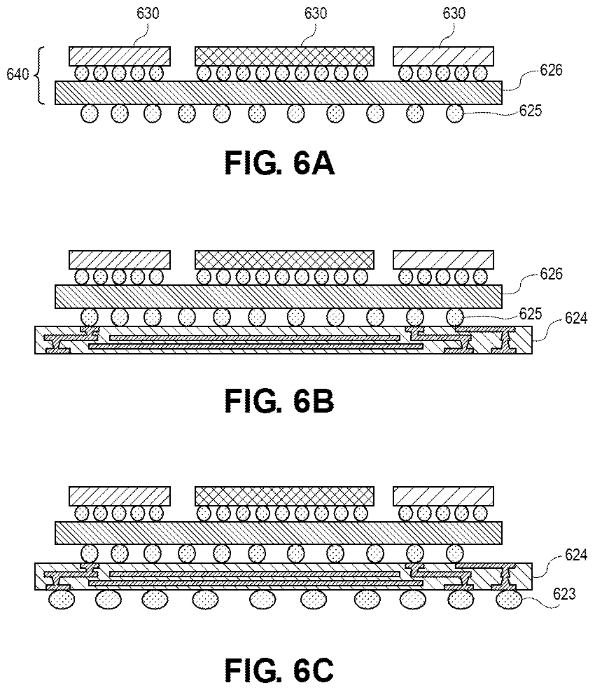

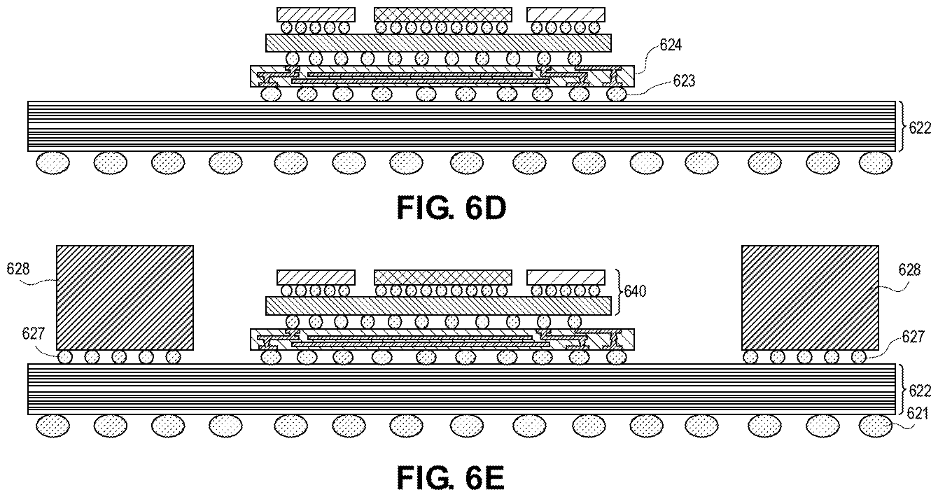

FIGS. 6A-6E illustrate stages in a manufacturing process for coupling an HDP substrate and one or more DRAM with an mSAP board, where a die complex is coupled with the HDP, in accordance with various embodiments. FIG. 6A shows a cross section side view of a stage of a manufacturing process that includes a die complex 640, which may be similar to die complex 340 of FIG. 3, which includes a base die 626, to which multiple dies 630 may be coupled. These may be similar to base die 226 and multiple dies 230 of FIG. 2A. In embodiments, the die complex 640 may be a die stack. The base die 626 may include PSB 625, which may be similar to PSB 225 of FIG. 2A, to facilitate physical and electrical coupling in subsequent manufacturing stages.

FIG. 6B shows a cross section side view of a stage in a manufacturing process where an HDP substrate 624, which may be similar to HDP substrate 224 of FIG. 2A, is coupled with the base die 626 using PSB 625. As described above, the HDP substrate 624 may be used as a pitch translator to translate a pitch of the base die 626 and of the PSB 625 to another larger pitch.

FIG. 6C shows a cross section side view of a stage in the manufacturing process where a BGA 623, which may be similar to BGA 223 of FIG. 2A, is coupled to the bottom of the HDP substrate 624. It should be noted that a pitch of the BGA 623 may be different, in particular may be greater than the pitch of the base die 626.

FIG. 6D shows a cross section side view of a stage in the manufacturing process where an mSAP board 622, which may be similar to mSAP board 222 of FIG. 2A, 322 of FIG. 3, or 422 of FIG. 4, is physically and electrically coupled with the HDP substrate 624 using BGA 623.

FIG. 6E shows a cross section side view of a stage in the manufacturing process where the RAM modules 628, which may be similar to DRAM modules 228 of FIG. 2A, may be physically and electrically coupled with the mSAP board 622. In embodiments, the coupling may be performed using BGA 627, which may be similar to BGA 227 of FIG. 2A. In embodiments, a BGA 621, which may be similar to BGA 221 of FIG. 2A, may be coupled to the bottom of the mSAP board 622. With this configuration, the die complex 640 is electrically and physically coupled with the DRAM 628 through the mSAP board 622.

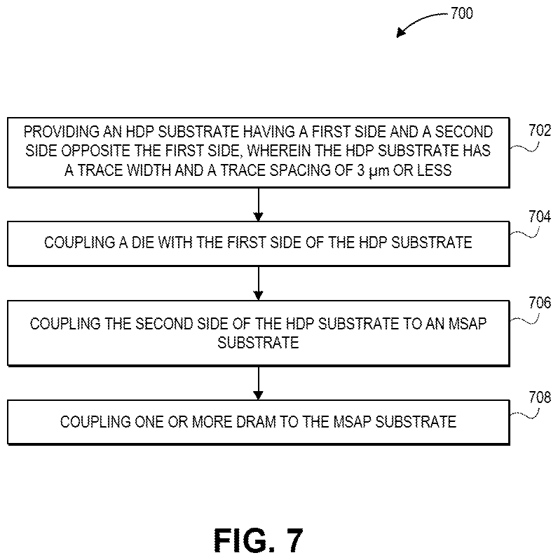

FIG. 7 illustrates an example process for coupling one or more DRAM and one or more HDP substrate with an mSAP board, in accordance with various embodiments. Process 700 may be performed by one or more elements, techniques, or systems that may be described herein, and in particular with respect to FIGS. 1-6E.

At block 702, the process may include providing an HDP substrate having a first side and a second side opposite the first side, wherein the HDP substrate has a trace width and a trace spacing of 3 μm or less. In embodiments, the HDP substrate may be similar to HDP substrate 624 of FIG. 6 or HDP substrate 224 of FIG. 2A.

At block 704, the process may further include coupling a die with the first side of the HDP substrate. In embodiments, the die may be similar to base die 226 of FIGS. 2A-2B, base die 326 of FIG. 3, or base die 626 of FIG. 6A. In embodiments, the die may also have other dies coupled with it, for example dies 230 of FIG. 2A, dies 330 of FIG. 3, or dies 630 of FIG. 6A.

At block 706, the process may further include coupling the second side of the HDP substrate to an mSAP substrate. In embodiments, the mSAP board may be similar to mSAP board 222 of FIG. 2A, mSAP board 322 of FIG. 3, mSAP board 422 of FIG. 4, mSAP board 522 of FIG. 5, or mSAP board 622 of FIGS. 6D-6E.

At block 708, the process may further include coupling one or more DRAM to the mSAP board. In embodiments, the one or more DRAM may be similar to DRAM 108 of FIG. 1, DRAM 228 of FIGS. 2A-2B, DRAM 528 of FIG. 5, or DRAM 628 of FIG. 6E.

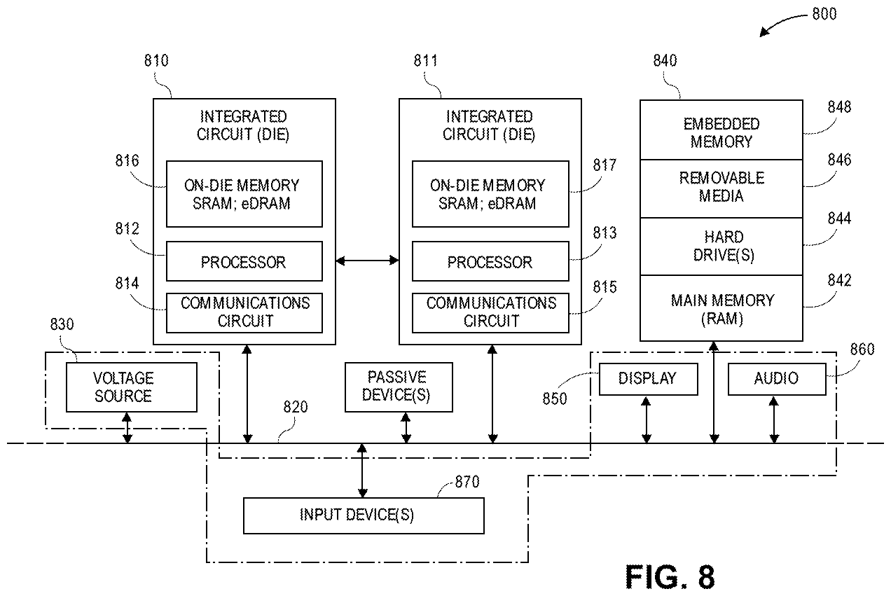

FIG. 8 is a schematic of a computer system 800, in accordance with an embodiment of the present invention. The computer system 800 (also referred to as the electronic system 800) as depicted can embody an HDP substrate and memory coupled to a mSAP board, according to any of the several disclosed embodiments and their equivalents as set forth in this disclosure. The computer system 800 may be a mobile device such as a netbook computer. The computer system 800 may be a mobile device such as a wireless smart phone. The computer system 800 may be a desktop computer. The computer system 800 may be a hand-held reader. The computer system 800 may be a server system. The computer system 800 may be a supercomputer or high-performance computing system.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes, or is coupled with, an HDP substrate and memory coupled to a mSAP board, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems, or a communications circuit for servers. In an embodiment, the integrated circuit 810 includes on-die memory 816 such as static random-access memory (SRAM). In an embodiment, the integrated circuit 810 includes embedded on-die memory 816 such as embedded dynamic random-access memory (eDRAM).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 810 includes embedded on-die memory 817 such as eDRAM.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in a die stack, according to an embodiment.

In an embodiment, the electronic system 800 also includes a display device 850, an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including a package substrate having an HDP substrate and memory coupled to a mSAP board, according to any of the several disclosed embodiments and their equivalents, an electronic system, a computer system, one or more methods of fabricating an integrated circuit, and one or more methods of fabricating an electronic assembly that includes a package substrate having an HDP substrate and memory coupled to a mSAP board, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having an HDP substrate and memory coupled to a mSAP board embodiments and their equivalents. A foundation substrate may be included, as represented by the dashed line of FIG. 8. Passive devices may also be included, as is also depicted in FIG. 8.

### EXAMPLES

The following paragraphs describe examples of various embodiments.

Example 1 is an apparatus comprising: a substrate with a first side and a second side opposite the first side, wherein the substrate has a first trace width and a first trace spacing that are less than or equal to 3 μm; and a die electrically and physically coupled with the first side of the substrate by an array of interconnects.

Example 2 may include the apparatus of example 1, or of any other example or embodiment herein, wherein the substrate is a HDP substrate.

Example 3 may include the apparatus of example 1, or of any other example or embodiment herein, wherein the die is a base die of a multi-die complex.

Example 4 may include the apparatus of example 1, or of any other example or embodiment herein, wherein the array of interconnects has a pitch of 110 μm or less between adjacent interconnects of the array of interconnects.

Example 5 may include the apparatus of example 1, or of any other example or embodiment herein, wherein the array of interconnects comprises a first array of interconnects, and wherein second side of the substrate has a second array of interconnects having a pitch of 210 μm or less between adjacent interconnects of the second array of interconnects.

Example 6 may include the apparatus of example 1, or of any other example or embodiment herein, wherein the die is a first die; and further comprising: a second die electrically and physically coupled with the first side of the substrate.

Example 7 may include the apparatus of example 1, or of any other example or embodiment herein, wherein the substrate is a first substrate; and wherein the die includes a second substrate; and further comprising one or more dies electrically and physically coupled with a side of the second substrate.

Example 8 is a package comprising: a first substrate having a first side and a second side opposite the first side; a second substrate having a first side and a second side opposite the first side, the second side of the second substrate electrically and physically coupled with the first side of the first substrate, and wherein the second substrate has a trace width and a trace spacing of 3 μm or less; one or more dies coupled with the first side of the second substrate; and one or more dynamic random-access memory (DRAM) electrically and physically coupled with the first side of the first substrate.

Example 9 may include the package of example 8, or of any other example or embodiment herein, wherein the first substrate is a modified semi-additive process (mSAP) board.

Example 10 may include the package of example 8, or of any other example or embodiment herein, wherein a pitch of the second side of the second substrate is less than or equal to 210 μm.

Example 11 may include the package of example 8, or of any other example or embodiment herein, wherein a pitch of the first side of the second substrate is less than or equal to 110 μm.

Example 12 may include the package of example 8, or of any other example or embodiment herein, wherein a distance between the first side of the second substrate and the first side of the first substrate is 200 μm or less.

Example 13 may include the package of example 8, or of any other example or embodiment herein, wherein the one or more dies further includes: a base die having a first side and a second side opposite the first side, wherein the second side of the base die is physically and electrically coupled with the first side of the second substrate; and a top die having a first side and a second side opposite the first side, wherein the second side of the top die is physically and electrically coupled with the first side of the base die.

Example 14 may include the package of example 13, or of any other example or embodiment herein, wherein a distance between the first side of the top die and the first side of the second substrate is 315 μm or less.

Example 15 may include the package of example 13, or of any other example or embodiment herein, wherein the base die includes active circuitry.

Example 16 may include the package of example 8, or of any other example or embodiment herein, wherein the one or more DRAM have a first side and a second side opposite the first side, wherein the second side of the one or more DRAM is physically and electrically coupled with the first side of the first substrate, and wherein a distance between the first side of the one or more DRAM and the first side of the first substrate is 900 μm or less.

Example 17 may include the package of example 16, or of any other example or embodiment herein, wherein a distance between the first side of the one or more DRAM and the second side of the first substrate is 1200 μm or less.

Example 18 may include the package of example 8, or of any other example or embodiment herein, wherein the first substrate includes a plurality of layers, wherein one or more of the plurality of layers are mSAP layers.

Example 19 may include the package of example 18, or of any other example or embodiment herein, wherein the plurality of layers include eight layers, and wherein two of the plurality of layers are mSAP layers.

Example 20 may include the package of example 19, or of any other example or embodiment herein, wherein layer 4 and layer 7 of the plurality of layers are mSAP layers.

Example 21 may include the package of example 8, or of any other example or embodiment herein, wherein a distance between the first side of the first substrate and the second side of the second substrate is 300 μm or less.

Example 22 is a method comprising: providing a hyper density package (HDP) substrate having a first side and a second side opposite the first side, wherein the HDP substrate has a trace width and a trace spacing of 3 μm or less; coupling a die with the first side of the HDP substrate; coupling the second side of the HDP substrate to a modified semi-additive process (mSAP) board; and coupling one or more dynamic random-access memory (DRAM) to the mSAP board.

Example 23 may include a method of example 22, or of any other example or embodiment herein, wherein the die is a base die of a multi-die complex.

Example 24 is an apparatus comprising: a substrate with a first side and a second side opposite the first side, wherein the substrate has a first trace width and a first trace spacing that are less than or equal to 3 μm; and a die electrically and physically coupled with the first side of the substrate by an array of interconnects.

Example 25 includes the apparatus of example 24, or of any other example or embodiment herein, wherein the substrate is a hyper density package (HDP) substrate.

Example 26 includes the apparatus of example 24, or of any other example or embodiment herein, wherein the die is a base die of a multi-die complex.

Example 27 includes the apparatus of example 24, or of any other example or embodiment herein, wherein the array of interconnects has a pitch of 110 μm or less between adjacent interconnects of the array of interconnects.

Example 28 includes the apparatus of example 24, or of any other example or embodiment herein, wherein the array of interconnects comprises a first array of interconnects, and wherein second side of the substrate has a second array of interconnects having a pitch of 210 μm or less between adjacent interconnects of the second array of interconnects.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus comprising:
a substrate with a first side and a second side opposite the first side, wherein the substrate has a first trace width and a first trace spacing that are less than or equal to 3 μm; and
a die electrically and physically coupled with the first side of the substrate by an array of interconnects.

2. The apparatus of claim 1, wherein the substrate is a hyper density package (HDP) substrate.

3. The apparatus of claim 1, wherein the die is a base die of a multi-die complex.

4. The apparatus of claim 1, wherein the array of interconnects has a pitch of 110 μm or less between adjacent interconnects of the array of interconnects.

5. The apparatus of claim 1, wherein the array of interconnects comprises a first array of interconnects, and wherein second side of the substrate has a second array of interconnects having a pitch of 210 μm or less between adjacent interconnects of the second array of interconnects.

6. The apparatus of claim 1, wherein the die is a first die; and further comprising:
a second die electrically and physically coupled with the first side of the substrate.

7. The apparatus of claim 1, wherein the substrate is a first substrate; and
wherein the die includes a second substrate; and
further comprising one or more dies electrically and physically coupled with a side of the second substrate.

8. A package comprising:
a first substrate having a first side and a second side opposite the first side;
a second substrate having a first side and a second side opposite the first side, the second side of the second substrate electrically and physically coupled with the first side of the first substrate, and wherein the second substrate has a trace width and a trace spacing of 3 μm or less;
one or more dies coupled with the first side of the second substrate; and
one or more dynamic random-access memory (DRAM) electrically and physically coupled with the first side of the first substrate.

9. The package of claim 8, wherein the first substrate is a modified semi-additive process (mSAP) board.

10. The package of claim 8, wherein a pitch of the second side of the second substrate is less than or equal to 210 μm.

11. The package of claim 8, wherein a pitch of the first side of the second substrate is less than or equal to 110 μm.

12. The package of claim 8, wherein a distance between the first side of the second substrate and the first side of the first substrate is 200 μm or less.

13. The package of claim 8, wherein the one or more dies further includes:
a base die having a first side and a second side opposite the first side, wherein the second side of the base die is physically and electrically coupled with the first side of the second substrate; and
a top die having a first side and a second side opposite the first side, wherein the second side of the top die is physically and electrically coupled with the first side of the base die.

14. The package of claim 13, wherein a distance between the first side of the top die and the first side of the second substrate is 315 μm or less.

15. The package of claim 13, wherein the base die includes active circuitry.

16. The package of claim 8, wherein the one or more DRAM have a first side and a second side opposite the first side, wherein the second side of the one or more DRAM is physically and electrically coupled with the first side of the first substrate, and wherein a distance between the first side of the one or more DRAM and the first side of the first substrate is 900 μm or less.

17. The package of claim 16, wherein a distance between the first side of the one or more DRAM and the second side of the first substrate is 1200 μm or less.

18. The package of claim 8, wherein the first substrate includes a plurality of layers, wherein one or more of the plurality of layers are mSAP layers.

19. The package of claim 18, wherein the plurality of layers include eight layers, and wherein two of the plurality of layers are mSAP layers.

20. The package of claim 19, wherein layer 4 and layer 7 of the plurality of layers are mSAP layers.

21. The package of claim 8, wherein a distance between the first side of the first substrate and the second side of the second substrate is 300 μm or less.

22. A method comprising:
providing a hyper density package (HDP) substrate having a first side and a second side opposite the first side, wherein the HDP substrate has a trace width and a trace spacing of 3 μm or less;
coupling a die with the first side of the HDP substrate;
coupling the second side of the HDP substrate to a modified semi-additive process (mSAP) board; and
coupling one or more dynamic random-access memory (DRAM) to the mSAP board.

23. The method of claim 22, wherein the die is a base die of a multi-die complex.
